(19) United States
(12) Patent Application Publication
(10) Pub. No.: US 2021/0165030 A1
(43) Pub. Date: Jun. 3, 2021

(54) METHOD FOR MEASURING TRAP PARAMETERS IN XLPE CABLE BASED ON POLARIZATION-DEPOLARZATION CURRENT TEST

(71) Applicant: SICHUAN UNIVERSITY, Chengdu (CN)

(72) Inventors: Kai Zhou, Chengdu (CN); Hao Yuan, Chengdu (CN); Mingzhi Li, Chengdu (CN); Yuan Li, Chengdu (CN); Hang Xi, Chengdu (CN)

(21) Appl. No.: 17/106,063

(22) Filed: Nov. 27, 2020

(30) Foreign Application Priority Data
Nov. 28, 2019 (CN) 201911193974.5

(51) Int. Cl. G01R 29/24; G01R 19/00; G01R 31/12

(52) U.S. Cl. CPC G01R 29/24; G01R 31/1272; G01R 19/0092

(57) ABSTRACT

Disclosed is a method for measuring trap parameters in an XLPE cable based on a polarization-depolarization current test. First a detrapping current is extracted from a polarization current, then the staged linear fitting is performed for the detrapping current. Fitting parameters Aₘ·τₘ and τₘ are used to represent trap parameters such as the trap charge density and the trap depth in the XLPE current. The trap charge density and charge accumulation of the XLPE cable insulation are reflected. This method can guarantee the accuracy and effectiveness of the trap parameter measurement. Furthermore, in the method, the staged linear fitting is performed for the detrapping current, providing an excellent fitting effect, effective elimination of various interference signals, and further accuracy improvement of the trap parameter measurement. In addition, the present disclosure is based on a PDC non-destructive test method.

### CROSS-REFERENCE TO RELATED APPLICATION(S)

This application claims the priority of China patent application No. 201911193974.5 filed on Nov. 28, 2019, disclosure of which is hereby incorporated by reference in its entirety.

### TECHNICAL FIELD

The present disclosure belongs to the technical field of high voltage and insulation, and relates to a method of trap measurement in an XLPE cable, in particular to a method for measuring the trap charge density and the trap depth in the XLPE cable based on a polarization-depolarization current test.

### BACKGROUND

As power transmission systems in China are increasingly growing in size, the application of a high-voltage DC cross-linked polyethylene (XLPE) cable is becoming more extensive. However, with the increasing voltage level and service life of the XLPE cable, it will be subjected to aging under the electricity, thermals and mechanical stresses, and micro-structural changes at the same time, such as creating traps. Carriers trapped in a medium forms space charges. The accumulation of space charges will cause distortion of the electric field distribution, and further accelerate the aging of insulation materials, even leading to insulation breakdown.

Trap characteristics in the XLPE cable can be obtained through measuring the space charge distribution in the XLPE cable. At present, main methods for measuring the space charge distribution in insulating materials include: the pulsed electro-acoustic method (PEA) and the pressure wave propagation method (PWP). However, these methods are problematic due to complex testing and signal processing processes, high precision requirements of instruments, and confined shapes of test materials, etc., and they cannot reflect material features such as trap depths. Researches have shown that the accumulation of trap charges can be reflected through measuring their detrapping current. A detrapping current refers to the current created by carriers (charges) escaping from a trap. Main methods for measuring the detrapping current include: the thermally stimulated current method (TSDC) and isothermally relaxed current method (IRC): (1) The IRC test method tests the isothermal relaxation current of a cable, and analyzes trap characteristics in the cable according to the measured isothermal relaxation current. However, the test result of the actual isothermal relaxation current contains the dipole relaxation current and the space charge detrapping current which cannot be distinguished from the isothermal relaxation current, and thus it is difficult to ensure the validity of the trap parameter measurement. (2) The TSDC test method obtains related trap parameters of carriers (charges) through observing process changes happening to the carriers from the low-temperature disequilibrium to the elevated-temperature thermal equilibrium, while widely ranged temperature adjustments are required for samples during the measurement, and the test system is quite complicated and difficult to apply to actual cable dimensions.

Therefore, there is still a lack of effective methods for measuring the space charge detrapping current and then analyzing trap depths and space charge accumulation in XLPE cable insulation materials.

### SUMMARY

To address the current difficulty of effective measurement and analysis of characteristics related to trap charges in an XLPE cable, the present disclosure is aimed at providing a method for measuring trap parameters in an XLPE cable based on the polarization-depolarization current test, which separates, from the polarization current, the detrapping current generated due to detrapping of the trap charges, and calculates trap depth and trap charge density parameters in an insulating medium by using the separated trap current.

According to the concept of the present disclosure, the polarization-depolarization current method (PDC) is widely applied in the diagnosis of insulating materials because of its advantages of nondestructive testing and abundant diagnostic information. The investigations have shown that, in the PDC test result, a polarization current contains a detrapping current which can be separated from the polarization current, and that the trap charge density and the corresponding trap depth of an insulating medium can be characterized.

The present disclosure provides a method for measuring trap parameters in an XLPE cable based on a polarization-depolarization current test, including:

(1) Obtaining a polarization current iₚₒₗ and a depolarization current i_{depol} through a polarization-depolarization current test performed on an XLPE cable;

(2) Calculating a detrapping current i_{de-trap} according to the following formula:

i_{de-trap}=(iₚₒₗ−i_{depol})−i_{construction};

wherein, i_{conduction} is a conduction current stable value;

(3) taking the logarithm of the detrapping current curve obtained in step (2), then dividing the logarithm-taken detrapping current curve into n linear segments, and correspondingly building n trap energy levels, with the m^{th} level Eₘ corresponding to a detrapping current component definition formula:

iₘ(t)=Aₘexp(−t/τₘ);

wherein, Aₘ is a fitting parameter, and τₘ is a residence time of charges staying in the trap built with the energy level Eₘ;

(4) conducting the staged linear fitting on respective linear segments of the logarithm-taken detrapping current curve according to lniₘ(t)=ln(Aₘexp(−t/τₘ)), resulting in Aₘ and τₘ; and further summing all stages of fitting curves together to get a fitting curve of the detrapping current as:

i_{de-trap}(t)=Σₘ₌₁ⁿiₘ(t)

(5) Obtaining the trap parameters, wherein Aₘ·τₘ and τₘ are respectively used to represent an accumulated charge density and a trap depth in a trap built with the energy level Eₘ, and the i_{de-trap}·t-lnt curve is used to represent a relationship between the trap charge density and its corresponding trap depth in the XLPE cable insulating medium.

According to the aforesaid method for measuring trap parameters in the XLPE cable based on the polarization-depolarization current test, there are a large number of defective parts in a polymer insulating medium which are caused by local non-uniformities of the polymer molecular structure. In these defective parts, polymer molecules often have a large affinity to carriers (such as charges) which easily attracts the carriers to fill in voids. This process is called the carrier capture, while these defect areas in the polymer molecular structure are called traps. When the carriers are trapped by the traps, they become trapped charges. The trap charges can escape from the traps and enter a conduction band by obtaining energy, and then leave the insulating medium to be released into an outer loop. A conductive current generated in this process is called a detrapping current of trap charges. If the detrapping current of trap charges may be measured, the trap charge density and the corresponding trap depth in the insulating medium can be calculated indirectly.

After ignoring the capacitance charging current and displacement polarization current in the polarization current, the polarization current iₚₒₗ mainly includes the dipole polarization current i_{dipole-pol}, the conductance current i_{conduction} and the trap charge detrapping current i_{de-trap}, namely:

iₚₒₗ−i_{dipole-pol}+i_{conduction}+i_{de-trap} (1);

wherein i_{dipole-pol} represents the current generated by dipole polarization; i_{de-trap} represents the current generated by charges escaping from the trap; i_{conduction} represents the conduction current of an insulating medium without charge injection, i.e., the steady-state value of the conduction composition in the polarization current.

In the depolarization stage of the XLPE cable, the tested insulating medium is grounded, and the depolarization current has a dipole relaxation current as its main composition. It is assumed that the polarization and relaxation process of dipoles is a linear process, which is:

i_{dipole-pol}=i_{depol} (2).

and then the conduction composition in the polarization current is:

iₚₒₗ−i_{depol}=i_{conduction}+i_{de-trap} (3);

Wherein, the detrapping current i_{de-trap} i of trap charges is attenuated over time, while the conduction current i_{conduction} is constant during polarization. Therefore, when the polarization time is long enough, the attenuation of the detrapping current i_{de-trap} becomes close to 0, with only i_{conduction} left in the right term of equation (3) at this moment which is the steady-state value of the conduction component in the polarization current, namely:

i_{conduction}=iₚₒₗ(t_{final})−i_{depol}(t_{final}) (4);

Wherein, iₚₒₗ (t_{final}) represents the polarization current after a set time for polarization of the XLPE cable, and i_{depol} (t_{final}) represents the depolarization current after a set time for depolarization of the XLPE cable.

Finally, by using formulas (3) and (4), the detrapping current i_{de-trap} can be obtained as:

i_{de-trap}=(iₚₒₗ−i_{depol})−[iₚₒₗ(t_{final})−i_{depol}(t_{final})] (5);

It is worth noting that there is no space charge injection and ionization during the polarization because the polarization voltage is not high during the PDC test. In addition, due to the Onsager effect, the charge recombination probability decreases in the presence of an electric field, so the charge recombination process is not put into consideration during the polarization.

According to the aforementioned method of the trap parameter measurement in the XLPE cable based on the polarization-depolarization current test, as detrapping currents of traps at all energy levels present attenuation exponential curves, and, however, it has been found through researches that the direct exponential function fitting shows poor effect, in the present disclosure, the detrapping current goes through the staged linear fitting.

The trap with an energy level Eₘ in the insulating medium correspond to the detrapping current

$${i}_{m} ( t ) ∝ \frac{{N}_{0} ( {E}_{m} )}{{τ}_{m}} exp ( - t \text{/} {τ}_{m} ) ,$$

wherein N₀(Eₘ) is an initial density of the trap with the energy level of Eₘ, and τₘ is the residence time of carriers (charges) staying in the trap with the energy level of Eₘ. As a result, the definition formula of the detrapping current component corresponding to the trap built with the trap energy level Eₘ constructed in the present disclosure is iₘ(t)=Aₘexp(−t/τₘ), Aₘ·τₘ∝N₀(Eₘ). Then, the detrapping current extracted from polarization current in previous steps is fitted in stages to obtain the detrapping currents corresponding to traps built with respective energy levels, and then the detrapping currents corresponding to the respective energy levels are combined to form a total detrapping current as i_{de-trap} (t)=Σₘ₌₁ⁿiₘ(t). Based on this formula, the detrapping current is linearly fitted in stages. Firstly, a logarithm is taken for the detrapping current obtained in step (2), and then the logarithm-taken detrapping current is substantially divided into n linear segments according to a slope (because the curve is fitted herein, an absolute linear segment is not necessary, and an approximate linear segment will be accepted). Then, the linear fitting is performed (such as by the least square method) on an ending linear segment of the logarithm-taken detrapping current curve to obtain a detrapping current fitting curve lni₁(t)=ln(A₁exp(−t/τ₁)) corresponding to a trap built with an energy level E₁, wherein A₁ is the fitted parameter, and τ₁ is a residence time of charges staying in the trap built with the energy level E₁. The fitted linear segment is removed from the logarithm-taken detrapping current curve and then the linear fitting is performed on (such as by the least square method) an ending linear segment of the remaining part of the logarithm-taken detrapping current curve to obtain a detrapping current fitting curve lni₂(t)=ln(A₂exp(−t/τ₂)) corresponding to a trap built with an energy level E₂, wherein 2 is the fitted parameter and T₂ a residence time of charges staying in the trap built with the energy level E₂. Proceeding in this way until the remaining part of the logarithm-taken detrapping current curve is a linear segment, and the linear fitting is again performed on this linear segment to obtain a detrapping current fitting curve lniₙ(t)=lₙ(Aₙexp(−t/τₙ)) corresponding to a trap built with an energy level Eₙ. Then, all pieces of fitted curves are summed up to obtain a fitting curve: i_{de-trap}(t)=Σₘ₌₁ⁿiₘ(t) of the detrapping current.

According to the aforementioned method for measuring trap parameters in an XLPE cable based on polarization-depolarization current test, since Aₘ·τₘ is proportional to the charge density N₀ (Eₘ), the charge density accumulated in the trap built with an energy level Eₘ can be represented by Aₘ·τₘ. Because the trap depth can be represented by the detrapping time, i. e., the longer the time constant is, the longer the detrapping time and the deeper the trap will be, τₘ may be used to represent the trap built with the energy level Eₘ. Because i_{de-trap}·t is the product of the detrapping current and time, i.e., the amount of detrapping charges, while lnt is proportional to the trap depth, the relationship between the trap charge density and the corresponding trap depth in the XLPE cable insulating medium can be expressed by the i_{de-trap}·t˜lnt curve.

In comparison to prior arts, the method provided in the present disclosure for measuring trap parameters in an XLPE cable based on the polarization-depolarization current test provides the following beneficial effects:

i In the present disclosure, firstly, the detrapping current is extracted from the polarization current, then the staged linear fitting is executed for the detrapping current, moreover, fitting parameters Aₘ·Lₘ and τₘ are used to represent trap parameters such as the trap charge density and trap depth in the XLPE current, and consequently, the trap charge density and charge accumulation of the XLPE cable insulation are reflected. As the present disclosure can accurately extract the detrapping current from the polarization current, it can guarantee the accuracy and effectiveness of the trap parameter measurement; and moreover, in the present disclosure, the staged linear fitting is executed for the detrapping current, resulting in an excellent fitting effect, effective elimination of various interference signals, and further accuracy improvement of the trap parameter measurement.

ii The i_{de-trap}·t˜lnt curve depicted by using the fitted parameters in the present disclosure may greatly represent the relationship between the trap charge density and the corresponding trap depth in the XLPE cable insulating medium.

iii The present disclosure is based on a PDC non-destructive test method without high requirements for test apparatuses, which is simple to operate, causes no damage to the cable insulation, and has very high practicability in terms of acquiring XLPE cable trap characteristics, making it suitable for promotion and application in this field.

### BRIEF DESCRIPTION OF THE DRAWINGS

FIG. 1 is a schematic diagram of the experimental principle of space charge injection adopted in an embodiment of the present disclosure; wherein 1 is a control box, 2 is a voltage-doubling cylinder, 3 is a current limiting resistor a, 4 is a micro-ammeter, 5 is a pin electrode, 6 is a plate electrode and 7 is a sample.

FIG. 2 is a schematic diagram of a PDC test principle adopted in an embodiment of the present disclosure; wherein 8 is a high voltage DC power supply, 9 is a single-pole double-throw relay, 10 is a current limiting resistor b, 11 is a pico-ammeter, 12 is a three-pole test unit, 121 is a high voltage electrode, 122 is a test electrode, 123 is a shield electrode, and 13 is an upper computer.

FIG. 3 is a schematic diagram of the fitting process of the detrapping current curve according to an embodiment of the present disclosure.

FIG. 4 illustrates the fitting result of the detrapping current curves measured on samples under different charge injection duration conditions according to an embodiment of the present disclosure.

FIG. 5 illustrates the i_{de-trap}·t˜lnt curves measured on the samples under different charge injection duration conditions according to an embodiment of the present disclosure.

FIG. 6 illustrates the fitting result of the detrapping current curves measured on the samples of different aging extents according to an embodiment of the present disclosure.

FIG. 7 illustrates i_{de-trap}·t˜lnt curve measured on the samples of different aging extents according to an embodiment of the present disclosure.

### DESCRIPTION OF THE EMBODIMENTS

The present disclosure will be specifically described by the following embodiment. It is necessary to point out that this embodiment is only used for further illustrating the present disclosure, but should not be understood as limiting the protection scope of the present disclosure. Those skilled in the art can make some non-essential improvements and adjustments to the present disclosure according to the above-mentioned contents of the present disclosure.

### EMBODIMENTS

5 circular XLPE sheets of a diameter of 10 cm and a thickness of 1 mm are selected as experimental samples. The samples are made by pressing polyethylene particles using a vacuum laminator and cross-linking them at 180 degrees Celsius and 15 Pa for 15 minutes, and the samples are degassed.

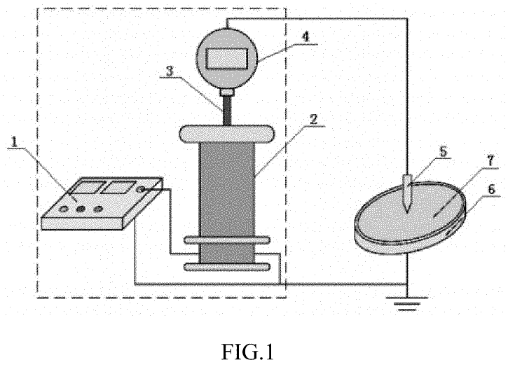

In this embodiment, the space charge injection method is the corona injection method, and the experimental principle of space charge injection adopted is shown in FIG. 1 which includes a DC high-voltage generator consisting of the control box 1, a voltage-doubling cylinder 2, a current limiting resistor a 3, and a micro-ammeter 4, as well as a pin electrode 5 and a plate electrode 6; wherein an output terminal of the control box 1 is connected to an input terminal of the voltage-doubling cylinder 2, a high-voltage output terminal of voltage-doubling cylinder is sequentially connected in series to the current limiting resistor a 3 and the micro-ammeter 4 before connected to the pin electrode 5 via wires. The control box ground terminal, the voltage-doubling cylinder ground terminal, and the plate electrode 6 are grounded via wires. The sample 7 is disposed between the pin electrode and the plate electrode with one side of the sample contacting the plate electrode closely and the other side keeps a 2 mm air gap away from the pin electrode. As a high-voltage DC power supply, the control box 1 applies a voltage to the pin electrode while gradually increases the voltage until a discharge halo layer appears at the pin tip (about a 45 kV high voltage is required). In this embodiment, a pin-plate motor is adopted to generate corona, and space charges ionized by the air gap are injected into samples.

4 of the samples are subjected to thermal aging treatment wherein the samples are put into a wet-temperature control box and treated by accelerated thermal aging under a thermal aging temperature of 135 degrees Celsius and a humidity of 0% for 2, 4, 6, and 8 days respectively. Then the space charges are injected into the XLPE cable samples according to the aforementioned process.

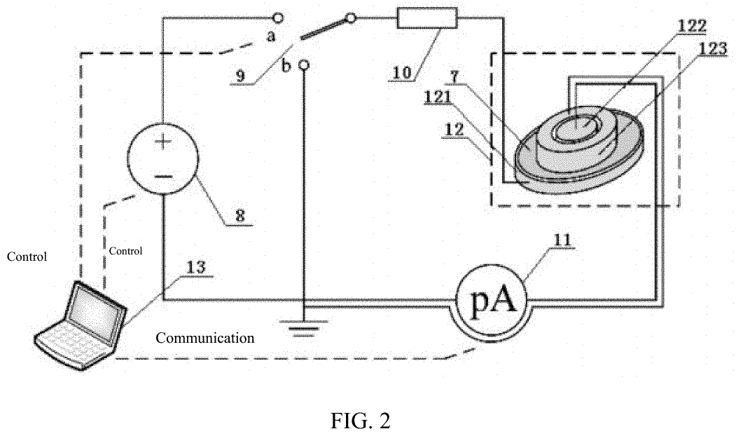

Then, the polarization-depolarization current (PDC) test is performed on the samples. The test schematic diagram is shown in FIG. 2 wherein the test apparatus includes a high-voltage DC power supply 8, a single-pole double-throw relay 9, a current limiting resistor b 10, a pico-ammeter 11, a three-pole test unit 12 and an upper computer 13. One terminal of the high-voltage DC power supply 8 is connected to the contact with contact a of the single-pole double-throw relay 9 through wires, the other terminal is connected with one terminal of the pico-ammeter 11 through wires. The other terminal of the pico-ammeter 11 is connected with a test electrode 122 of a three-pole test unit 12 via wires. The pole of the single-pole double-throw relay 2 is connected with one terminal of the current limiting resistor b 10 via wires, while the other terminal of current limiting resistor b 10 is connected with the test electrode 122 of the three-pole test unit 12 via wires. A contact b of the single-pole double-throw relay 2 and a shield electrode 123 of the three-pole test unit 12 are both grounded via wires, and the high-voltage DC power supply 8, the single-pole double-throw relay 9 and the pico-ammeter 11 are all connected with the upper computer 13 through transmission lines. The upper computer 13 controls the high-voltage DC power supply and the single-pole double-throw relay, and carries out real-time acquisition of the pico-ammeter data.

Based on the aforementioned test apparatus, the trap parameters of samples are measured according to the trap parameter measurement method in an XLPE cable provided in this embodiment as follows:

(1) Obtaining the polarization current iₚₒₗ and the depolarization current i_{depol} of an XLPE cable by performing a polarization-depolarization current test on the XLPE cable.

The process of performing the polarization-depolarization current test on the samples by using the aforementioned test apparatus includes: controlling the single-pole double-throw relay through the upper computer; when connecting the pole to the contact a, applying a polarization voltage of 4 kV through the high-voltage DC power supply to the cable sample for polarization; after a polarization period t₁ (1000 seconds in the embodiment) elapses, controlling the single-pole double-throw relay to switch and connect the pole to the contact b; grounding the samples; discharging through the current limiting resistor b and carrying out depolarization of which a duration is t₂ (1000 seconds in the embodiment). The pico-ammeter measures the polarization current iₚₒₗ during polarization and measures depolarization current i_{depol} during depolarization, respectively.

(2) Calculating a detrapping current i_{de-trap} according to the following formula:

i_{de-trap}=(iₚₒₗ−i_{depol})−i_{conduction};

i_{conduction}=iₚₒₗ(t_{final})−i_{depol}(t_{final});

iₚₒₗ (t_{final}) represents the polarization current after 1000 seconds of polarization performed on the XLPE cable; i_{depol} (t_{final}) represents the depolarization current after 1000 seconds of depolarization performed on the XLPE cable.

(3) taking the logarithm of the detrapping current curve obtained in step (2), then dividing the logarithm-taken detrapping current curve into n linear segments, and correspondingly building n trap energy levels, with the m^{th} level Eₘ corresponding to a detrapping current component definition formula:

iₘ(t)−Aₘexp(−t/τₘ);

wherein, Aₘ is a fitting parameter, and τₘ is a residence time of charges staying in the trap built with the energy level Eₘ.

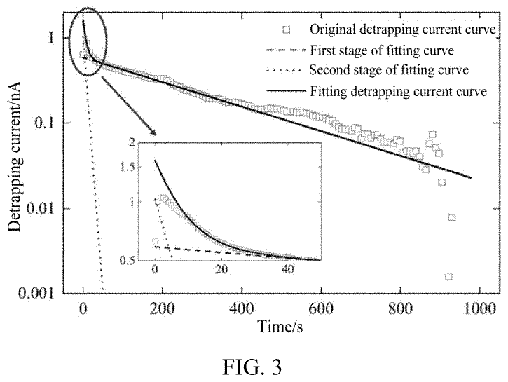

Taking the logarithm of the detrapping current extracted from the polarization current in step (2) in this embodiment, as shown in FIG. 3, it can be seen that the logarithm-taken detrapping current (the coordinates of the detrapping current are logarithmic coordinates) is apparently divided into two linear segments, on the basis of which two trap energy levels (E₁ and E₂ respectively) can be built and the definition formula of the detrapping current component of a trap at each energy level is as described above.

(4) Conducting the staged linear fitting on respective linear segments of the logarithm-taken detrapping current curve according to lniₘ(t)−ln(Aₘexp(−t/τₘ)), resulting in Aₘ and τₘ, and further summing all stages of fitting curves up to get a fitting curve of the detrapping current as:

i_{de-trap}(t)=Σₘ₌₁ⁿiₘ(t).

In this embodiment, the fitting process of the detrapping current curve corresponding to the sample aged for 2 days (with a charge injection duration of 30 minutes) is explained in detail. At first, an ending linear segment of the logarithm-taken detrapping current curve is fitted linearly by using the least square method, in order to obtain a detrapping current fitting curve (corresponding to the dashed line) lni₁(t)=ln(A₁exp(−t/τ₁)) corresponding to a trap built with a trap energy level E₁, wherein A₁ is the fitting parameter and τ₁ is the residence time of charges staying in the trap built with the trap energy level E₁. The fitted linear segment is removed from the logarithm-taken detrapping current curve, and then the least-square-method linear fitting is performed on an ending linear segment of the remaining part of the logarithm-taken detrapping current curve to obtain a detrapping current fitting curve lni₂(t)=ln(A₂exp(−t/τ₂)) (corresponding to the dotted line) corresponding to a trap built with a trap energy level E₂, wherein A₂ is the fitting parameter, and τ₂ is the residence time of charges staying in the trap built with the trap energy level E₂. Further, all stages of fitting curves are summed up to get a fitting curve (the solid portion) of the detrapping current as: (solid line): i_{de-trap}=A₁exp(−t/τ₁)+A₂exp(−t/τ₂).

(5) Obtaining the trap parameters, wherein Aₘ·τₘ and τₘ are respectively used to represent an accumulated charge density and a trap depth in a trap built with an energy level Eₘ, and the i_{de-trap}·t˜lnt curve is used to represent a relationship between the trap charge density and its corresponding trap depth in the XLPE cable insulating medium.

In this embodiment, as the fitting curve of the detrapping current can be expressed as i_{de-trap}=A₁exp(−t/τ₁)+A₂exp (−t/τ₂), A₁·τ₁ and τ₁ are used to represent the accumulated charge density and the trap depth in the trap built with the energy level E₁, A₂·τ₂ and τ₂ are respectively used to represent the accumulated charge density and the trap depth in the trap built with the energy level E₂, and i_{de-trap}·t˜lnt is used to represent the relationship between the trap charge density and its corresponding trap depth in the XLPE cable insulating medium in this embodiment. The trap characteristics of the XLPE cable can be obtained by analyzing the change trends of A₁·τ₁, τ₁, A₂·τ₂, τ₂ and i_{de-trap}·t˜lnt.

Verifying the effectiveness of the extraction method of the detrapping current and the calculation method of the trap density provided in the present disclosure

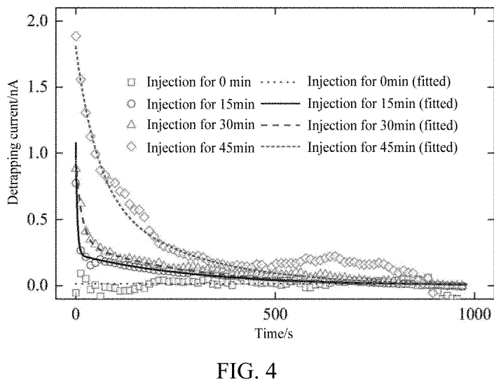

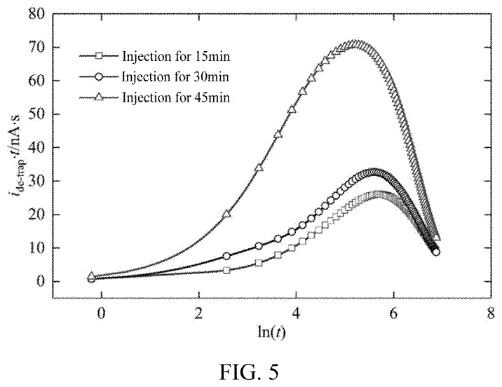

The charge injection durations (0, 15 min, 30 min, 45 min in turn, with a short-circuit heat cleaning (at 100 degrees Celsius for 24 hours) performed between every two experiments to eliminate any influence arising from the space charge injection history) are changed for a sample not aged yet. Then, the sample is tested according to the aforementioned steps (1)-(5) to obtain the corresponding trap parameters, with the test results shown in Table 1, FIGS. 4 and 5.

TABLE 1
Fitting parameters of detrapping current after space charge
injection performed on a sample for different durations

| Injection | | | | |
|---|---|---|---|---|
| Durations | A₁ · τ₁/(A · s) | τ₁/(s) | A₂ · τ₂/(A · s) | τ₂/(s) |
| i5 min | 3.316 × 10⁻⁹ | 3.957 | 7.102 × 10⁻⁸ | 299.158 |
| 30 min | 9.525 × 10⁻⁹ | 15.209 | 8.889 × 10⁻⁸ | 269.542 |
| 45 min | 5.646 × 10⁻⁸ | 53.619 | 1.812 × 10⁻⁷ | 240.964 |

Fitting curves of the detrapping current after space charge injection performed on the sample for different durations are shown in FIG. 4. It can be seen in FIG. 4 that as the space charge injection duration increases, the detrapping current obtained by the PDC test becomes larger. This is because with the increase of injection duration, more charges are injected into the insulating medium. At the same time, it also shows that the extraction method of the detrapping current provided in the present disclosure is effective.

Fitting parameters of the detrapping current after space charge injection performed on the sample for different durations are shown in Table 1, and i_{de-trap}·t˜lnt curve is shown in FIG. 5. As the injection duration increases, the parameter τ₁ increases, the parameter T₂ decreases, while parameters A₁·τ₁ and A₂·τ₂ both increase, and the peak value of i_{de-trap}·t˜lnt curve moves to the top left. Because the sample is not aged yet, the trap depth in the sample does not change. Therefore, even if the charge injection duration changes, the parameters τ₁ and τ₂ should not change. As mentioned above, the parameters τ₁ and τ₂ respectively represent two different trap depths (set as ΔE₁ and ΔE₂, wherein ΔE₁<ΔE₂) built in the sample. With the increase of charge injection duration, the amount of charges accumulated in the trap within the sample increases. Over a same duration, when the charge accumulation in the trap of the depth ΔE₃ (ΔE₁<ΔE₃<ΔE₂) is larger than those in the traps of depths ΔE₁ and ΔE₂, the parameters τ₁ and τ₂ will approach the τ value (i.e., τ₃) corresponding to the trap of the depth ΔE₃, showing that the parameter τ₁ increases while the parameter τ₂ decreases. Therefore, the changes happening to the parameter τₘ, parameter Aₘ·τₘ and curve i_{de-trap}·t˜lnt indicate that the amounts of charges captured by deep and shallow traps both increases, while charges accumulate in the middle-deep trap faster than in deep and shallow traps. That is, as the charge injection duration increases, it is easier to accumulate charges in the middle-deep trap than in deep traps and shallow traps. Therefore, the trap parameters τₘ, Aₘ·τₘ and the curve i_{de-trap}·t˜lnt proposed by the present disclosure can better represent the trap characteristics in the XLPE cable.

Researches for the relationship between the trap charge trap current and sample aging degree, and verifications for the effectiveness of representing trap characteristics in the XLPE cable by using fitting parameters of the trap current curve extracted from the polarization current

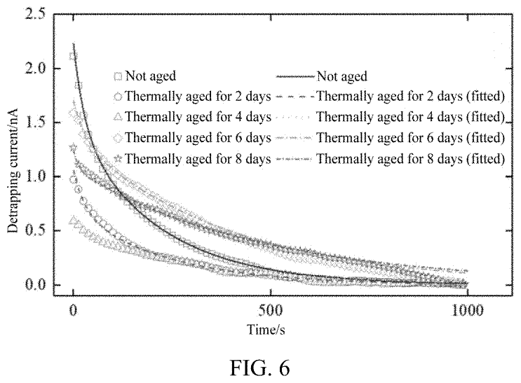

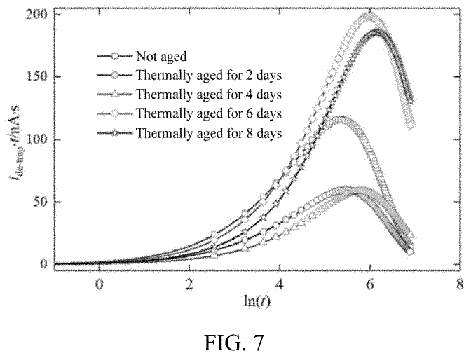

According to the aforementioned steps (1)-(5), tests are performed on samples with different aging degrees after the charge injection (with the charge injection duration of 30 minutes) to get the corresponding trap parameters, as shown in Table 2, FIGS. 6 and 7.

TABLE 3
Fitting parameters of detrapping current curve
of samples with different aging degrees

| Thermal Aging | | | | |
|---|---|---|---|---|
| Durations | A₁ · τ₁/(A · s) | τ₁/(s) | A₂ · τ₂/(A · s) | τ₁/(s) |
| 0 d | 2.061 × 10⁻⁸ | 27.218 | 3.147 × 10⁻⁷ | 212.766 |
| 2 d | 1.095 × 10⁻⁸ | 29.360 | 1.622 × 10⁻⁷ | 235.849 |
| 4 d | 3.702 × 10⁻⁹ | 23.502 | 1.587 × 10⁻⁷ | 326.797 |
| 6 d | 1.001 × 10⁻⁸ | 29.223 | 5.397 × 10⁻⁷ | 396.825 |
| 8 d | 5.741 × 10⁻⁹ | 26.287 | 5.051 × 10⁻⁷ | 471.698 |

It can be observed from FIG. 6 that with the increase of accelerated thermal aging duration, the amplitude of an initial stage of the detrapping current of the sample first decreases and then increases. After accelerated thermal aging for 2 days, the amplitude of the detrapping current reaches the bottom, while after thermal aging for 6 days, the amplitude at the ending stage of the detrapping current increases substantially. This trend becomes more obvious for trap parameters τₘ, Aₘ·τₘ and the characteristic curve i_{de-trap}˜t˜lnt.

The fitting parameters of the detrapping current of samples with different aging degrees are shown in Table 2, and the corresponding i_{de-trap}·t˜lnt curve is shown in FIG. 7. It can be seen from Table 2 and FIG. 7 that with the increase of thermal aging duration, the parameter τ₁ is basically unchanged, the parameter τ₂ substantially increases, while the parameters A₁·τ₁ and A₂·τ₂ both decrease at first and then increase. The peak value of i_{de-trap}·t˜lnt curve decreases at the initial stage of thermal aging, and rises when thermal aging comes to a certain extent, and moves to the right obviously as the thermal aging proceeds. These phenomena indicate that: (1) the thermal aging increases the trap depth in the sample; (2) in the initial aging stage, the amount of trapped charges decreases which indicates that the number of deep and shallow traps decreased; (3) then as the thermal aging is intensified, the amount of trapped charges gradually increases, indicating that the number of deep and shallow traps is increasing. This is because in the initial stage of thermal aging, i.e., the recrystallization stage, the temperature promotes the re-crosslinking of the incompletely crosslinked part in the material, which is beneficial for improving the crystallization of the insulating material, resulting in a decrease in the number of traps. However, as the aging duration increases, the sample aging comes into the thermal oxidation stage, wherein the temperature begins to destroy the crystalline region in the material, leading to the increase of amorphous regions in the material as well as more traps.

Apparently, those skilled in the art can make various modifications and variations without departing from the spirit and scope of the present disclosure. In this way, if these modifications and variations of the present disclosure fall within the scope of the claims and their equivalents, the present disclosure is also intended to incorporate these modifications and variations.

What is claimed is:

1. A method for measuring trap parameters in an XLPE cable based on a polarization-depolarization current test, the method comprising:
obtaining a polarization current iₚₒₗ and a depolarization current i_{depol} through a polarization-depolarization current test performed on an XLPE cable;
calculating a detrapping current i_{de-trap} according to the following formula:
i_{de-trap}=(iₚₒₗ−i_{depol})−i_{conduction}; wherein,i_{conduction} is a conduction current stable value;
taking the logarithm of the detrapping current curve obtained in step (2), dividing the logarithm-taken detrapping current curve into a number of n linear segments, and correspondingly building n trap energy levels, with the m^{th} level Eₘ corresponding to a detrapping current component definition formula:
iₘ(t)=Aₘexp(−t/τₘ); wherein,Aₘ is a fitting parameter, and τₘ is a residence time of charges staying in the trap built with the energy level Eₘ;
conducting the staged linear fitting on respective linear segments of the logarithm-taken detrapping current curve according to lniₘ(t)=ln(Aₘexp(−t/τₘ)), thus obtaining Aₘ and τₘ; and further summing all stages of fitting curves to obtain a fitting curve of the detrapping current as:
i_{de-trap}(t)=Σₘ₌₁ⁿiₘ(t); and
obtaining the trap parameters, wherein Aₘ·τₘ and τₘ respectively represent an accumulated charge density and a trap depth in the trap built with an energy level Eₘ, and an i_{de-trap}·t˜lnt curve is used to represent a relationship between the trap charge density and its corresponding trap depth in an XLPE cable insulating medium.

2. The method as recited in claim 1, wherein the conduction current stable value i_{conduction} is obtained according to the following formula:
i_{conduction}=iₚₒₗ(t_{final}·)-i_{depol}(t_{final});
wherein, iₚₒₗ (t_{final}) represents the polarization current after a set time for polarization of the XLPE cable, and i_{depol} (t_{final}) represents the depolarization current after a set time for depolarization of the XLPE cable.

3. The method as recited in claim 1, wherein the staged linear fitting of the detrapping current in step (4) comprises:
performing linear fitting on an ending linear segment of the logarithm-taken detrapping current curve to obtain a detrapping current fitting curve lni₁(t)=ln(A₁exp(−t/τ₁)) corresponding to a trap built with an energy level E₁, wherein A₁ is a fitting parameter, and τ₁ is a residence time of charges staying in the trap built with the energy level E₁;
removing fitted linear segments from the logarithm-taken detrapping current curve and then performing linear fitting on an ending linear segment of the remaining part of the logarithm-taken detrapping current curve to obtain a detrapping current fitting curve lni₂(t)=ln(A₂exp(−t/τ₂)) corresponding to a trap built with an energy level E₂;
proceeding in this way until the remainder of the logarithm-taken detrapping current curve is a linear segment, and proceeding to perform linear fitting on this linear segment to obtain a detrapping current fitting curve lniₙ(t)=ln(Aₙexp(−t/τₙ)) corresponding to a trap built with an energy level Eₙ; and
summing all fitting curves to obtain a fitting curve of the detrapping current as:
i_{de-trap}(t)=Σₘ₌₁ⁿiₘ(t).

4. The method as recited in claim 2, wherein the staged linear fitting of the detrapping current in step (4) comprises:
performing linear fitting on an ending linear segment of the logarithm-taken detrapping current curve to obtain a detrapping current fitting curve lni₁(t)=ln(A₁exp(−t/τ₁)) corresponding to a trap built with an energy level E₁, wherein A₁ is a fitting parameter, and τ₁ is a residence time of charges staying in the trap built with the energy level E₁;
removing fitted linear segments from the logarithm-taken detrapping current curve and then performing linear fitting on an ending linear segment of the remaining part of the logarithm-taken detrapping current curve to obtain a detrapping current fitting curve lni₂(t)=ln(A₂exp(−t/τ₂)) corresponding to a trap built with an energy level E₂;
proceeding in this way until the remainder of the logarithm-taken detrapping current curve is a linear segment, and proceeding to perform linear fitting on this linear segment to obtain a detrapping current fitting curve lniₙ(t)=ln(Aₙexp(−t/τₙ)) corresponding to a trap built with an energy level Eₙ; and
summing all fitting curves to obtain a fitting curve of the detrapping current as:
i_{de-trap}(t)=Σₘ₌₁ⁿiₘ(t),
